(19) United States
(12) Patent Application Publication
(10) Pub. No.: US 2016/0259454 A1
(43) Pub. Date: Sep. 8, 2016

(54) TOUCH UNIT, TOUCH SUBSTRATE AND MANUFACTURING METHOD THEREOF, AND FLEXIBLE TOUCH DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Jiuxia YANG, Beijing (CN); Jiantao LIU, Beijing (CN); Feng BAI, Beijing (CN)

(73) Assignees: BEIJING BOE OPTOELECTRONICS TECHNOLOGY CO., LTD., Beijing (CN); BOE TECHNOLOGY GROUP CO., LTD., Beijing (CN)

(21) Appl. No.: 14/743,294

(22) Filed: Jun. 18, 2015

(30) Foreign Application Priority Data
Mar. 3, 2015 (CN) 201510094730.7

(51) Int. Cl. G06F 3/041; C23C 14/58; C23C 14/06; C23C 14/24

(52) U.S. Cl. CPC G06F 3/0412; C23C 14/24; C23C 14/5826; C23C 14/0605; G06F 2203/04102; G06F 2203/04103

(57) ABSTRACT

A touch unit, a touch substrate and a manufacturing method thereof, and a flexible touch display device are disclosed. The touch unit comprises a composite graphene layer which at least comprises a first graphene layer and a second graphene layer. An inorganic material layer is disposed between the first graphene layer and the second graphene layer and reduces the impedance of the first graphene layer and the second graphene layer. The touch unit has good mechanical and electrical properties and hence can be well applied to flexible touch display products.

### TECHNICAL FIELD

Embodiments of the present invention relate to a touch unit, a touch substrate and a manufacturing method thereof, and a flexible touch display device.

### BACKGROUND

Touch units are usually made from a transparent conductive material (e.g., indium tin oxide, ITO), a metal mesh, etc. But the materials have poor mechanical strength and flexibility, so that the touch units made from the materials cannot be well applied to flexible display products.

Graphene is of a planar film in which hexagonal honeycomb lattices are formed by sp2 hybrid orbitals of carbon atoms, is also a two-dimensional (2D) material with the thickness of only one carbon atom, only has the thickness of 0.335 nm, and is currently the world's thinnest and hardest nano-material. The material is almost fully transparent and only has the incident light absorption rate of 2.3%. The thermal conductivity is up to 5,300 W/m·K. Graphene has good electronic conductivity, has the electron mobility of higher than 15,000 cm2/V·s at the room temperature, only has the electric resistivity of 10⁻⁶ Ω·cm, and is currently a material with the lowest electric resistivity in the world. Because graphene is a superior transparent conductive film with high transmittance, high conductivity, high flexibility, high mechanical strength and high thermal conductivity, graphene has a great advantage in the future flexible touch display field.

### SUMMARY

At least one embodiment of the present invention provides a touch unit and a manufacturing method thereof, and a flexible touch display device, so that the touch unit has good mechanical properties and flexibility and lower impedance characteristic and hence can be well applied to flexible touch display products.

At least one embodiment of the present invention provides a touch unit, which comprises a composite graphene layer which at least comprises a first graphene layer and a second graphene layer. An inorganic material layer is disposed between the first graphene layer and the second graphene layer and reduces the impedance of the first graphene layer and the second graphene layer.

For instance, the composite graphene layer comprises more than two graphene layers and at least one inorganic material layer; and each inorganic material layer is disposed between two adjacent graphene layers.

For instance, the inorganic material layer comprises one or more selected from the group consisting of BaF2, MgF2 and FeCl3.

At least one embodiment of the present invention provides a touch substrate, which comprises a base substrate provided with the foregoing touch units.

For instance, the touch substrate comprises a plurality of layers of touch units; and an insulating layer is disposed between every two layers of touch units.

At least one embodiment of the present invention provides a touch display device, which comprises the foregoing touch substrate.

For instance, the touch substrate is curved or bent; and at least one touch unit on the touch substrate is disposed in a non-display area.

At least one embodiment of the present invention provides a method for manufacturing a touch substrate, which comprises: forming a first graphene layer on a base substrate; forming an inorganic material layer on the first graphene layer; forming a second graphene layer on the inorganic material layer so as to form a composite graphene layer, in which the inorganic material layer reduces the impedance of the first graphene layer and the second graphene layer; and patterning the composite graphene layer to form a plurality of touch units.

For instance, the first graphene layer and the second graphene layer are formed by bonding a graphene film.

For instance, the inorganic material layer is formed by vacuum evaporation.

For instance, the inorganic material layer comprises one or more selected from the group consisting of BaF2, MgF2 and FeCl3.

For instance, the step of patterning the composite graphene layer to form the plurality of touch units comprises: forming a PMMA layer on the composite graphene layer; forming an electrode pattern on the PMMA layer via a predetermined mold;

forming an electrode pattern on the composite graphene layer by plasma processing technology; and removing the PMMA layer.

For instance, the electrode pattern is formed on the PMMA layer by nano-imprint technology via the predetermined mold.

At least one embodiment of the present invention provides another method for manufacturing a touch substrate, which comprises: forming a first graphene layer provided with an electrode pattern on a base substrate; forming an inorganic material layer on the first graphene layer; and forming a second graphene layer provided with an electrode pattern on the inorganic material layer, so as to form a composite graphene layer. The inorganic material layer reduces the impedance of the first graphene layer and the second graphene layer.

For instance, the first graphene layer and the second graphene layer provided with the electrode patterns are formed by bonding graphene films provided with the electrode patterns.

### BRIEF DESCRIPTION OF THE DRAWINGS

Simple description will be given below to the accompanying drawings of the embodiments to provide a more clear understanding of the technical proposals of the embodiments of the present invention. Obviously, the drawings described below only involve some embodiments of the present invention but are not intended to limit the present invention.

FIG. 1 is a schematic structural view of a touch unit provided by an embodiment 1;

FIG. 2 is a schematic structural view of a touch unit provided by an embodiment 2;

FIG. 3 is a flowchart of a method for manufacturing a touch substrate, provided by an embodiment 5;

FIG. 4 is a schematic diagram illustrating the technical process of forming a composite graphene layer in step 101 of the embodiment 5;

FIG. 5 is a flowchart of the process for forming the composite graphene layer in the step 101 of the embodiment 5;

FIG. 6 is a schematic diagram illustrating the technical process of patterning the composite graphene layer in step 102 of the embodiment 5;

FIG. 7 is a flowchart of the process for patterning the composite graphene layer in the step 102 of the embodiment 5; and

FIG. 8 is a flowchart of the process for forming the composite graphene layer by another means in step 201 of an embodiment 6.

### DETAILED DESCRIPTION

For more clear understanding of the objectives, technical proposals and advantages of the embodiments of the present invention, clear and complete description will be given below to the technical proposals of the embodiments of the present invention with reference to the accompanying drawings of the embodiments of the present invention. Obviously, the preferred embodiments are only partial embodiments of the present invention but not all the embodiments. All the other embodiments obtained by those skilled in the art without creative efforts on the basis of the embodiments of the present invention illustrated shall fall within the scope of protection of the present invention.

It should be noted that the words “first” and “second” in the application are only intended to distinguish two entities and do not mean that the two entities have difference in structure and composition, namely the first graphene layer and the second graphene layer may have no difference in structure and composition, and of course, may also have some difference according to actual needs.

Because the mechanical properties and the impedance characteristics of touch units made from graphene only are not very satisfactory, a new touch unit structure is needed to fully utilize the properties of the graphene and achieve better mechanical properties and lower impedance characteristics on this basis.

### EMBODIMENT 1

FIG. 1 is a schematic structural view of a touch unit provided by the embodiment 1. As illustrated in FIG. 1, the touch unit provided by the embodiment 1 comprises a composite graphene layer which comprises a first graphene layer 1 and a second graphene layer 3. An inorganic material layer 2 is disposed between the first graphene layer 1 and the second graphene layer 3 and reduces the impedance of the first graphene layer 1 and the second graphene layer 3.

As single-layer graphene is theoretically of a monatomic structure, if an appropriate inorganic material layer is disposed between two graphene layers, inorganic materials are connected with adjacent graphene layers through bonded structures. Therefore, after the appropriate inorganic material layer is arranged, the impedance of graphene materials adjacent to the inorganic material layer is reduced. Generally, the inorganic material layer comprises one or more selected from the group consisting of BaF2, MgF2 and FeCl3.

Therefore, the touch unit formed by the composite graphene layer comprising the graphene layers and the inorganic material layer has good mechanical properties and flexibility, e.g., properties such as bending resistance, scratch resistance and knock resistance, so that the touch unit can be well applied to flexible touch display products. In addition, as the touch unit has good mechanical properties and flexibility, the touch unit can be continuously disposed on several adjacent surfaces (e.g., the side surface and the back surface) of a touch panel, so that the defect that the touch unit can only be disposed on a main display panel can be overcome, namely the touch unit provided by the present invention can be applied to expand a touch area of a display device. Moreover, as the inorganic material layer is disposed between upper and lower graphene layers of the touch unit, the touch unit also has high transmittance and low impedance.

In addition, as the touch unit provided by the embodiment can be disposed on the side surface or the back surface of the touch panel, the display device manufactured with the touch unit provided by the embodiment can perform some instruction operations of the display device without lighting up the screen, in conjunction with internal system procedures of the display device. Therefore, the energy consumption can be saved, and hence the life of the display device can be prolonged.

### EMBODIMENT 2

The touch unit provided by the embodiment 2 comprises a composite graphene layer which comprises more than two graphene layers and at least one inorganic material layer. Each inorganic material layer is disposed between two adjacent graphene layers. The inorganic material layer reduces the impedance of the two graphene layers disposed on and beneath the inorganic material layer.

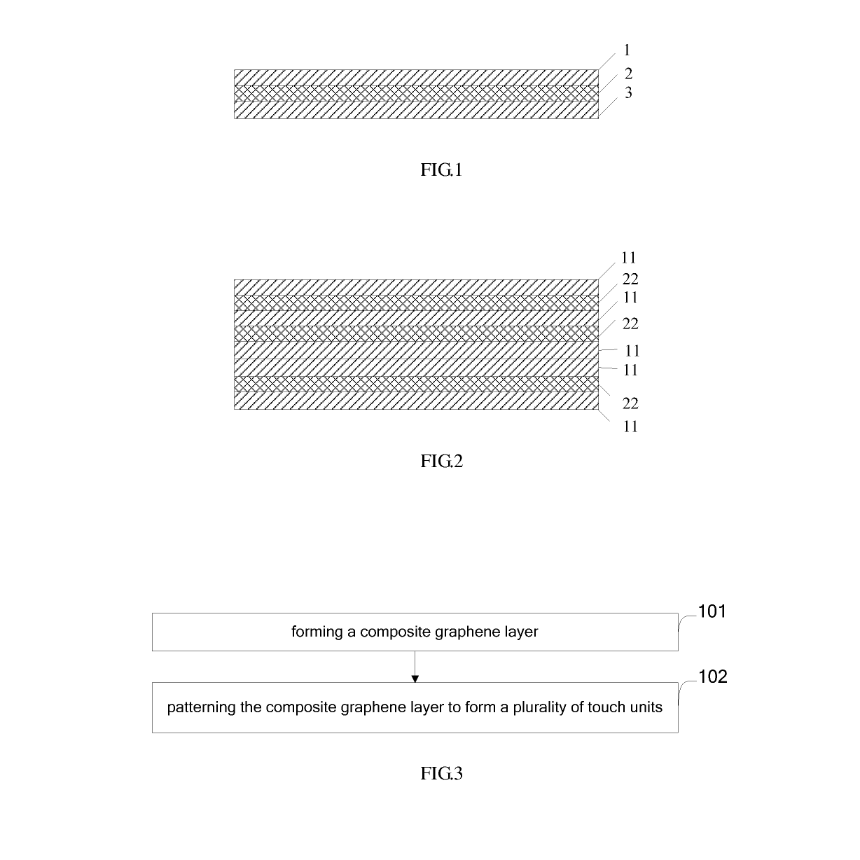

As illustrated in FIG. 2, the touch unit provided by one example of the embodiment comprises a composite graphene layer which comprises five graphene layers 11 and three inorganic material layers 22. The inorganic material layer 22 is disposed between two graphene layers 11 and reduces the impedance of the two graphene layers 11 disposed on and beneath the inorganic material layer 22.

For instance, the inorganic material layer comprises one or more selected from the group consisting of BaF2, MgF2 and FeCl3.

The touch unit provided by the embodiment is formed by the composite graphene layer consisting of the graphene layers and the inorganic material layers and has good mechanical properties and flexibility, e.g., properties such as bending resistance, scratch resistance and knock resistance, so that the touch unit can be well applied to flexible touch display products. In addition, as the touch unit has good mechanical properties and flexibility, the touch unit can be continuously disposed on several adjacent surfaces (e.g., the side surface and the back surface) of a touch panel, so that the defect that the touch unit can only be disposed on a main display panel can be overcome, namely the touch unit provided by the present invention can be applied to expand a touch area of a display device. Moreover, as the inorganic material layer is disposed between upper and lower graphene layers of the touch unit, the touch unit also has high transmittance and low impedance.

In addition, as the touch unit provided by the embodiment can be disposed on the side or the back of the touch panel, the display device manufactured with the touch unit provided by the embodiment can complete some instruction operations of the display device without lighting up the screen, in conjunction with internal system procedures of the display device. Therefore, the energy consumption can be saved, and hence the life of the display device can be prolonged.

### EMBODIMENT 3

The embodiment 3 provides a touch substrate, which comprises a base substrate provided with the touch units provided by the embodiment 1 or the embodiment 2.

When the touch substrate needs a plurality of layers of touch units, an insulating layer is disposed between every two layers of touch units.

The touch substrate provided by the embodiment comprises the touch units provided by the embodiments 1 and 2 and hence has the same advantages with the embodiments 1 and 2.

### EMBODIMENT 4

The embodiment 4 provides a touch display device, which comprises the touch substrate provided by the embodiment 3. The touch substrate may be curved or bent. At least one touch unit on the touch substrate is disposed in a non-display area, namely the touch unit may be disposed in a non-display area or other areas on the side surface or the back surface of the touch display device or the surface of a display area.

The touch display device provided by the embodiment comprises the touch substrate provided by the embodiment 3 and hence has the same advantages with the embodiment 3. In addition, the touch display device provided by the embodiment may comprise one or more touch substrates provided by the embodiment 3. The touch substrates may be disposed on any surface or several surfaces of the touch display device in a curved or bent configuration.

### EMBODIMENT 5

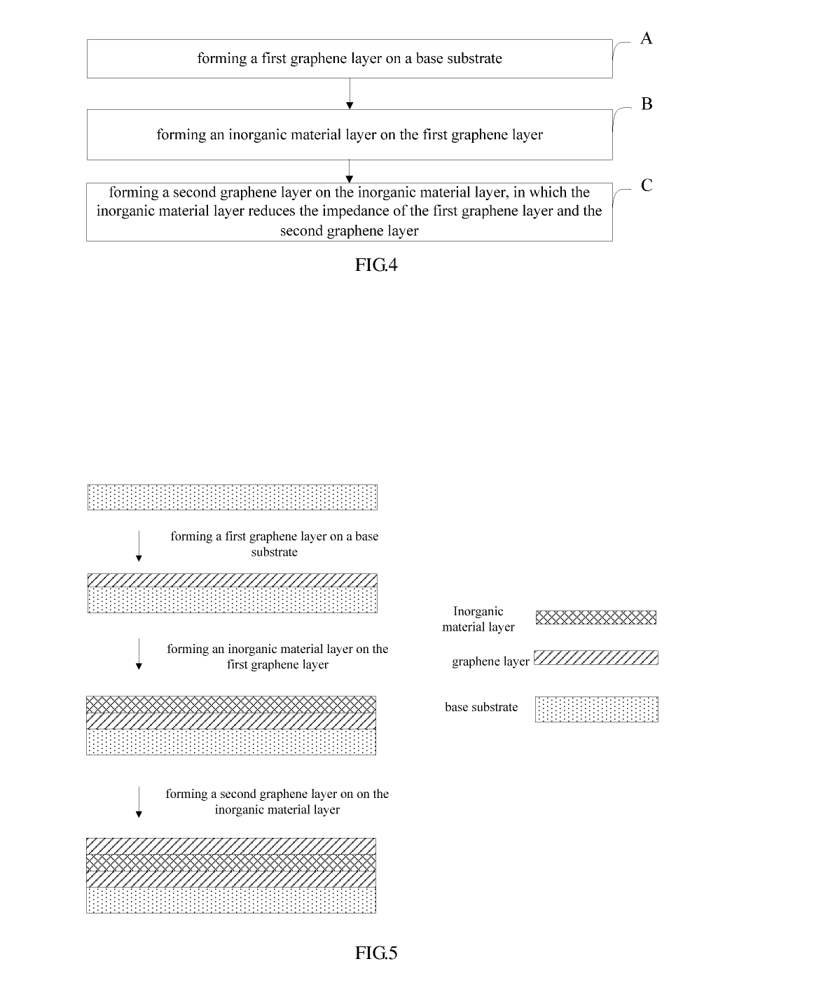

FIG. 3 is a flowchart of a method for manufacturing a touch substrate, provided by the embodiment 5. The touch substrate is the touch substrate provided by the above embodiment. The manufacturing method comprises:

S101: forming a composite graphene layer.

S102: patterning the composite graphene layer to form a plurality of touch units.

The technical process of forming the composite graphene layer in the step S101 is as shown in FIG. 4. The flowchart of the process for forming the composite graphene layer in the step S101 is as shown in FIG. 5. As illustrated in FIGS. 4 and 5, the step S101 may comprise the following sub-steps:

Step A: forming a first graphene layer on a base substrate.

In the step, the first graphene layer may be formed on the base substrate by bonding/attaching a graphene film. Herein, the base substrate may be a common passivation layer and may be a touch panel. If the first graphene layer is formed on the passivation layer and the subsequent steps are continuously finished, the formed touch units are also required to be transferred to the touch panel. If the first graphene layer is directly formed on the touch panel and the subsequent steps are continuously finished, the formed touch units are not required to be transferred.

Step B: forming an inorganic material layer on the first graphene layer.

In the step, the inorganic material layer may be formed by vacuum evaporation for example. The inorganic material layer comprises one or more selected from the group consisting of BaF2, MgF2 and FeCl3.

Step C: forming a second graphene layer on the inorganic material layer, in which the inorganic material layer reduces the impedance of the first graphene layer and the second graphene layer.

In the step, as the same as the forming process of the first graphene layer, the second graphene layer may be formed by bonding/attaching a graphene film.

The steps A, B and C may be used for manufacturing the touch unit provided by the embodiment 1.

For instance, the composite graphene layer may further comprise more than two graphene layers and at least one inorganic material layer. Each inorganic material layer is disposed between two adjacent graphene layers. At this point, the process of forming the composite graphene layer in the step S101 is as follows.

Step A1: forming a graphene layer on a base substrate.

Step B1: forming an inorganic material layer on the graphene layer.

The steps A1 and B1 are repeated for a plurality of times according to actual needs, and the final step is A1, so that the uppermost layer is a graphene layer. Meanwhile, the step A1 may be repeated for a plurality of times without the interval of the step B1 as required, namely a plurality of graphene layers that are directly stacked together.

The inorganic material layer reduces the impedance of two graphene layers disposed on and beneath the inorganic material layer.

The above method may be used for manufacturing the touch unit provided by the embodiment 2.

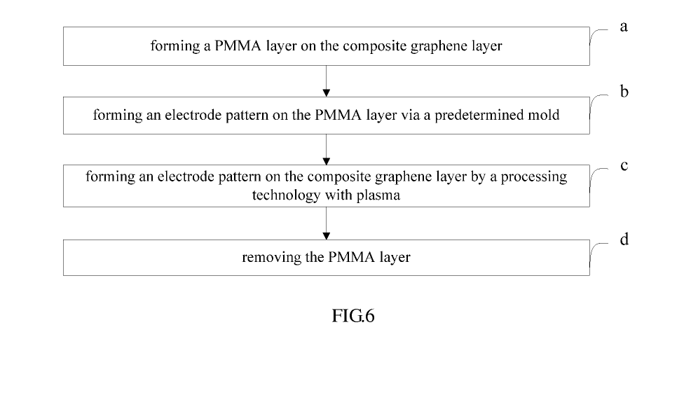

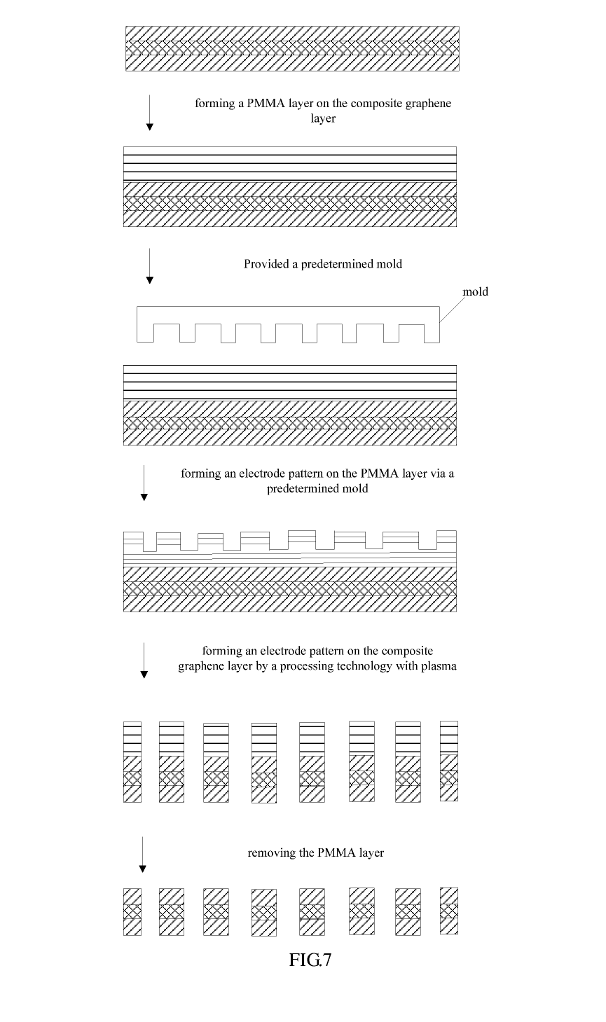

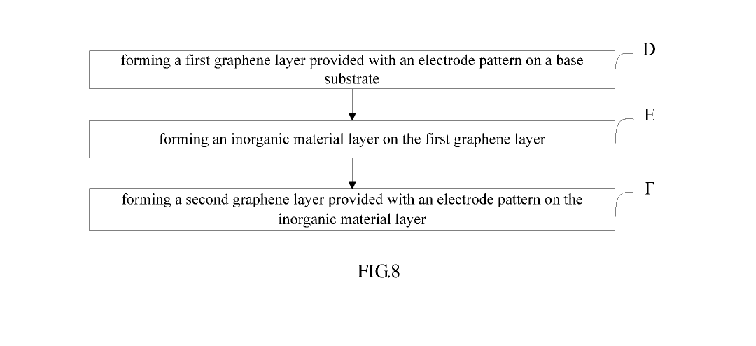

FIG. 6 is a schematic diagram illustrating the technical process of patterning the composite graphene layer in the step S102. FIG. 7 is a flowchart of the process for patterning the composite graphene layer in the step S102. As illustrated in FIGS. 6 and 7, the process of patterning the composite graphene layer to form the plurality of touch units in the step S102 comprises the following steps.

Step a: forming a PMMA layer on the composite graphene layer.

In the step, the PMMA layer may be formed by coating liquid PMMA and curing the liquid PMMA on the composite graphene layer.

Step b: forming an electrode pattern on the PMMA layer via a predetermined mold.

In the step, the electrode pattern may be formed on the PMMA layer by nano-imprint technology via the predetermined mold (or die).

Step c: forming an electrode pattern on the composite graphene layer by a processing technology with plasma.

Step d: removing the PMMA layer.

Particularly, as for the touch substrate comprising the plurality of touch units, an insulating layer is disposed between every two layers of touch units.

The method for manufacturing the touch substrate, provided by the embodiment, may be used for manufacturing the touch substrate provided by the embodiment 3.

### EMBODIMENT 6

The embodiment 6 provides another method for manufacturing a touch substrate. The method is different from the manufacturing method provided by the embodiment 5. The method for manufacturing the touch substrate, provided by the embodiment, comprises the following steps:

S201: forming a composite graphene layer.

For instance, FIG. 8 is a flowchart of the process for forming the composite graphene layer in another way in the step 201. As illustrated in FIG. 8, the process of forming the composite graphene layer in the step S201 comprises the following sub-steps:

D: forming a first graphene layer provided with an electrode pattern on a base substrate.

In the step, the first graphene layer provided with the electrode pattern may be formed by bonding/attaching a graphene film provided with the electrode pattern.

E: forming an inorganic material layer on the first graphene layer.

In the step, as the same as the method of forming the inorganic material layer in the embodiment 5, the inorganic material layer may be formed by vacuum evaporation. The inorganic material layer comprises one or more selected from the group consisting of BaF2, MgF2 and FeCl3.

F: forming a second graphene layer provided with an electrode pattern on the inorganic material layer, in which the inorganic material layer reduces the impedance of the first graphene layer and the second graphene layer.

In the step, the second graphene layer provided with the electrode pattern may be formed by bonding/attaching a graphene film provided with the electrode pattern.

Compared with the embodiment 5, in the embodiment, as the graphene layer is formed by the graphene film provided with the electrode pattern and etched in advance, the step of etching the electrode pattern on the composite graphene layer in the embodiment 5 is omitted.

For instance, the composite graphene layer may further comprise more than two graphene layers and at least one inorganic material layer. The inorganic material layer is disposed between graphene layers. At this point, the process of forming the composite graphene layer in the step S201 comprises the following steps:

Step DE forming a graphene layer provided with an electrode pattern on a base substrate.

Step E1: forming an inorganic material layer on the graphene layer.

The steps D1 and E1 are repeated for a plurality of times according to actual needs, in which the final step is D1, so that the uppermost layer is the graphene layer provided with the electrode pattern. Meanwhile, the step D1 may be repeated for a plurality of times without the interval of the step E1 as required, namely a plurality of graphene layers are directly stacked together. The inorganic material layer reduces the impedance of two graphene layers disposed on and beneath the inorganic material layer.

The foregoing is only the preferred embodiments of the present invention and not intended to limit the scope of protection of the present invention. The scope of protection of the present invention should be defined by the appended claims.

The application claims priority to the Chinese patent application No. 201510094730.7, filed Mar. 3, 2015, the disclosure of which is incorporated herein by reference as part of the application.

What is claimed is:

1. A touch unit, comprising a composite graphene layer, wherein the composite graphene layer at least comprises a first graphene layer and a second graphene layer; and an inorganic material layer is disposed between the first graphene layer and the second graphene layer and reduces the impedance of the first graphene layer and the second graphene layer.

2. The touch unit according to claim 1, wherein the composite graphene layer comprises more than two graphene layers and at least one inorganic material layer; and each inorganic material layer is disposed between two adjacent graphene layers.

3. The touch unit according to claim 1, wherein the inorganic material layer comprises one or more selected from the group consisting of BaF2, MgF2 and FeCl3.

4. The touch unit according to claim 2, wherein the inorganic material layer comprises one or more selected from the group consisting of BaF2, MgF2 and FeCl3.

5. A touch substrate, comprising a base substrate provided with at least one touch unit according to claim 1.

6. The touch substrate according to claim 5, further comprising a plurality of layers of touch unit, wherein an insulating layer is disposed between every two layers of touch unit.

7. A touch display device, comprising the touch substrate according to claim 5.

8. The touch display device according to claim 7, wherein the touch substrate further comprises a plurality of layers of touch unit; and an insulating layer is disposed between every two layers of touch unit.

9. The touch display device according to claim 8, wherein the touch substrate is curved or bent; and at least one touch unit on the touch substrate is disposed in a non-display area.

10. A method for manufacturing a touch substrate, comprising:
forming a first graphene layer on a base substrate;
forming an inorganic material layer on the first graphene layer;
forming a second graphene layer on the inorganic material layer so as to form a composite graphene layer, in which the inorganic material layer reduces the impedance of the first graphene layer and the second graphene layer; and
patterning the composite graphene layer to form a plurality of touch units.

11. The method for manufacturing the touch substrate according to claim 10, wherein the first graphene layer and the second graphene layer are formed by bonding/attaching a graphene film.

12. The method for manufacturing the touch substrate according to claim 10, wherein the inorganic material layer is formed by vacuum evaporation.

13. The method for manufacturing the touch substrate according to claim 10, wherein the inorganic material layer comprises one or more selected from the group consisting of BaF2, MgF2 and FeCl3.

14. The method for manufacturing the touch substrate according to claim 8, wherein the process of patterning the composite graphene layer to form the plurality of touch units comprises:
forming a polymethyl methacrylate (PMMA) layer on the composite graphene layer;
forming an electrode pattern on the PMMA layer via a predetermined mold;
forming an electrode pattern on the composite graphene layer by a processing technology with plasma; and
removing the PMMA layer.

15. The method for manufacturing the touch substrate according to claim 14, wherein the electrode pattern is formed on the PMMA layer by nano-imprint technology via the predetermined mold.

16. The method for manufacturing the touch substrate according to claim 10, wherein the composite graphene layer comprises more than two graphene layers and at least one inorganic material layer; and each inorganic material layer is disposed between two adjacent graphene layers.

17. A method for manufacturing a touch substrate, comprising:
forming a first graphene layer provided with an electrode pattern on a base substrate;
forming an inorganic material layer on the first graphene layer; and
forming a second graphene layer provided with an electrode pattern on the inorganic material layer, so as to form a composite graphene layer, in which the inorganic material layer reduces the impedance of the first graphene layer and the second graphene layer.

18. The method for manufacturing the touch substrate according to claim 16, wherein the first graphene layer and the second graphene layer provided with the electrode patterns are formed by bonding graphene films provided with the electrode patterns.

19. The method for manufacturing the touch substrate according to claim 17, wherein the composite graphene layer comprises more than two graphene layers and at least one inorganic material layer; and each inorganic material layer is disposed between two adjacent graphene layers.
